(19) United States
(12) Patent Application Publication
(10) Pub. No.: US 2024/0038999 A1
(43) Pub. Date: Feb. 1, 2024

(54) Composite current collector, method of making the same, and battery thereof

(71) Applicant: Aplus Semiconductor Technologies Co., Ltd., Changzhou City (CN)

(72) Inventor: SUI-HO TSAI, Changzhou City (CN)

(21) Appl. No.: 17/943,235

(22) Filed: Sep. 13, 2022

(30) Foreign Application Priority Data
Jul. 26, 2022 (CN) 202210886362.X

(51) Int. Cl. H01M 4/66

(52) U.S. Cl. CPC H01M 4/667; H01M 4/661

(57) ABSTRACT

A composite current collector contains: a substrate and a composite portion formed on at least one surface of the substrate. The composite portion includes a connection layer, a conductive layer, and an insulation layer. The conductive layer is located on the connection layer, and the insulation layer is defined between the connection layer and the conductive layer. A first side of the insulation layer is connected with the connection layer, and a second side of the insulation layer is connected with the conductive layer. The insulation layer is configured to stop an action of the connection layer to the conductive layer. Thereby, reaction of the conductive layer to the connection layer is eliminated by the insulation layer to enhance connection strength of the composite portion and the substrate, thus prolonging the service life of the composite current collector.

### BACKGROUND OF THE INVENTION

### 1. Field of the Invention

The present invention relates to a composite current collector, and more particularly to the composite current collector, a method of making the same, and a battery thereof.

### 2. Description of the Prior Art

A current collector is a structure or part that collects current. At present, the current collectors on lithium-ion batteries are usually made of copper foil or aluminum foil. However, when the current collector is made of metal materials, the cost of the raw materials used is higher, and the weight of the battery is heavier. At present, a PET composite copper/aluminum foil has been developed in the prior art to replace the traditional copper foil or aluminum foil. PET composite copper/aluminum foil is a bonding layer sputtered on the surface of PET, and then a conductive layer is processed on the surface of the bonding layer. The main function of the bonding layer is to connect the PET and the conductive layer. However, when the battery is charged and discharged, the temperature rises, which accelerates the diffusion reaction between the conductive layer and the bonding layer, resulting in a decrease in the bonding force between the bonding layer and PET, which eventually leads to the peeling of the conductive layer, the safety and reliability of the battery become worse, and a service life is shortened.

### SUMMARY OF THE INVENTION

The primary object of the present invention is to provide a composite current collector, a method of making the same, and a battery thereof which is capable of overcoming the shortcomings of the conventional composite current collector, method of making the same, and battery thereof.

It is seen that after the test, a connection section of the conductive layer 50 and the connection layer 30 produces a diffusion reaction so that connection strength of the connection layer 30 and the substrate 10 is reduced. After providing the insulation layer 40, reaction of the conductive layer 50 to the connection layer is eliminated to enhance connection strength of the composite portion 20 and the substrate 10, thus prolonging the service life of the composite current collector.

To obtain the above-mentioned object, a composite current collector provided by the present invention contains:
a substrate;
a composite portion formed on at least one surface of the substrate), wherein the composite portion includes:
a connection layer connected on the at least one surface of the substrate;
a conductive layer located on the connection layer; and
an insulation layer defined between the connection layer and the conductive layer. A first side of the insulation layer is connected with the connection layer, and a second side of the insulation layer is connected with the conductive layer. The insulation layer is configured to stop an action of the connection layer to the conductive layer.

The insulation layer is made of at least one of metals or alloys which include copper, aluminum, chromium, tin, cobalt, tungsten, zinc, and nickel.

A thickness of the insulation layer is 2 nanometers (nm) to 50 nanometers (nm).

The substrate is any one of polyethylene terephthalate (PET), polypropylene (PP), polyimide (PI), polycarbonate (PC), and poly (methyl methacrylate) (PMMA), wherein a thickness of the substrate is 2 microns to 15 microns.

The connection layer is made of at least one of metals or alloys which include copper, aluminum, chromium, titanium, vanadium, niobium, cobalt, tungsten, molybdenum, zinc, and nickel, wherein a thickness of the connection layer is 2 nm to 50 nm.

The composite current collector as claimed in claim 2, wherein the conductive layer is made of at least one of copper, aluminum, lithium, gold, silver, titanium, molybdenum, zinc, and nickel.

The composite current collector as claimed in claim 6, wherein the insulation layer is made of different material from the material of the material of the conductive layer.

The composite current collector as claimed in claim 1, wherein the weather-resistant layer is made of any one of metals, alloys, metal oxides, and antioxidants, wherein the metals and the alloys of the weather-resistant layer include at least one of copper, aluminum, gold, silver, titanium, chromium, tin, cobalt, tungsten, molybdenum, zinc, and nickel, wherein thickness of the weather-resistant layer is 2 nm to 100 nm.

A method of making a composite current collector as claimed in claim 1, comprises steps of:
S1) sputtering the connection layer on the substrate;
S2) sputtering the insulation layer on the connection layer;
S3) sputtering a seed layer on the insulation layer;
S4) forming a metal layer on the seed layer, wherein the conductive layer is defined by the metal layer and the seed layer;
S5) forming the weather-resistant layer on the metal layer;
wherein in the step S4), the metal layer is formed in an electroplating manner or an evaporating manner;
wherein in the step S5), the weather-resistant layer is formed in any one of an electroplating manner, a chemical reacting manner, and a coating manner, the materials of the metal layer are identical to the materials of the seed layer, wherein a thickness of the seed layer 5-1 is 2 nm to 100 nm, a thickness of the metal layer is 0.5 nm to 5 nm.

A battery as claimed in claim 1 is made of the composite current collector.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 is a cross sectional view showing the assembly of a composite current collector according to a preferred embodiment of the present invention.

### DETAILED DESCRIPTION OF THE PREFERRED EMBODIMENTS

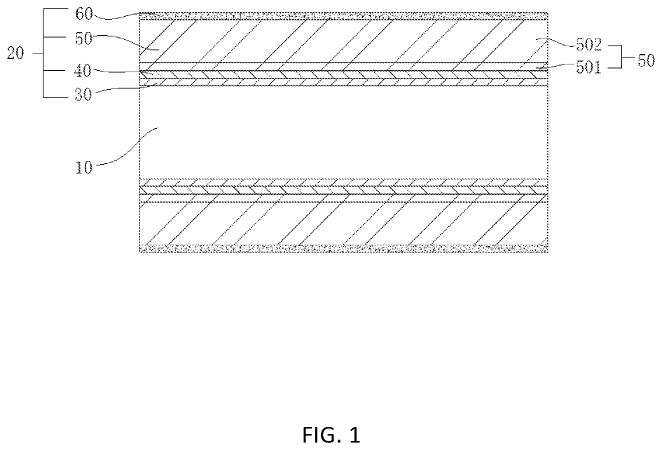

Referring to FIG. 1, a composite current collector according to a preferred embodiment of the present invention comprises a substrate 10 and a composite portion 20 formed on at least one surface of the substrate 10, and the composite portion 20 includes: a connection layer 30, a conductive layer 50, and an insulation layer 40, wherein the connection layer 30 is connected on the at least one surface of the substrate 10; the conductive layer 50 is located on the connection layer 30; and the insulation layer 40 is defined between the connection layer 30 and the conductive layer 50, wherein a first side of the insulation layer 40 is connected with the connection layer 30, and a second side of the insulation layer 40 is connected with the conductive layer 50, wherein the insulation layer 40 is configured to stop an action of the connection layer 30 to the conductive layer 50.

The insulation layer 40 is made of at least one of metals or alloys which include copper, aluminum, chromium, tin, cobalt, tungsten, zinc, and nickel. Furthermore, a thickness of the insulation layer 40 is 2 nanometers (nm) to 50 nanometers (nm). In other words, the insulation layer 40 is any one of copper, aluminum, chromium, tin, cobalt, tungsten, zinc, nickel, copper alloys, aluminum alloys, chromium alloys, tin alloys, cobalt alloys, tungsten alloys, zinc alloys, nickel alloys. Preferably, the insulation layer 40 is made at least one of the alloys. Compared with the at least one of the metals, the alloys are reacted less with the metals and have outstanding insulation effect.

The substrate 10 is any one of polyethylene terephthalate (PET), polypropylene (PP), polyimide (PI), polycarbonate (PC), and poly (methyl methacrylate) (PMMA), wherein a thickness of the substrate 10 is 2 microns to 15 microns. Compared with conventional copper foil or aluminum foil, the substrate 10 of the present invention is replaced by non-metallic materials to reduce a weight greatly.

The connection layer 30 is made of at least one of metals or alloys which include copper, aluminum, chromium, titanium, vanadium, niobium, cobalt, tungsten, molybdenum, zinc, and nickel. Furthermore, a thickness of the connection layer 30 is 2 nm to 50 nm. In other words, the substrate layer 10 is made of non-metallic materials, and the conductive layer 50 is made of metals. To connect the metals on the non-metallic materials, the connection layer 30 is formed so that the substrate 10 is metalized, then the connection layer 30 is formed on the substrate 10.

Preferably, the insulation layer 40 is made of different material from the material of the material of the conductive layer 50, such that the insulation layer 40 is configured to stop the action of the connection layer 30 to the conductive layer 50 greatly. Preferably, the insulation layer 40 is made of at least one of the alloys.

The conductive layer 50 is made of at least one of copper, aluminum, lithium, gold, silver, titanium, molybdenum, zinc, and nickel. When the conductive layer 50 is made of one of copper, aluminum, lithium, gold, silver, titanium, molybdenum, zinc, and nickel, excellent conductivity is obtained. The conductive layer 50 is applicable for various batteries, taking a lithium battery for example, when the conductive layer 50 of the composite current collector is applicable for negative electrode of the lithium battery, the conductive layer 50 is made of copper. When the conductive layer 50 of the composite current collector is applicable for anode of the lithium battery, the conductive layer 50 is made of aluminum.

In another embodiment, a weather-resistant layer 60 is formed on an outer surface of the conductive layer 50, and the weather-resistant layer 60 is made of any one of metals, alloys, metal oxides, and antioxidants, wherein the metals and the alloys of the weather-resistant layer 60 include at least one of copper, aluminum, gold, silver, titanium, chromium, tin, cobalt, tungsten, molybdenum, zinc, and nickel. A thickness of the weather-resistant layer 60 is 2 nm to 100 nm.

The weather-resistant layer 60 is configured to protect the conductive layer 50 to avoid corrosion of the conductive layer 50, wherein the weather-resistant layer 60 is made of any one of metals, alloys, metal oxides, and organic antioxidants. The metals of the weather-resistant layer 60 are at least one of copper, aluminum, lithium, gold, silver, titanium, chromium, tin, cobalt, tungsten, molybdenum, zinc, and nickel. The alloys of the weather-resistant layer 60 are at least one of copper alloys, aluminum alloys, lithium alloys, gold alloys, silver alloys, titanium alloys, chromium alloys, tin alloys, cobalt alloys, tungsten alloys, molybdenum alloys, zinc alloys, and nickel alloys. The metal oxides of the weather-resistant layer 60 are at least one of copper metal oxides, aluminum metal oxides, lithium metal oxides, gold metal oxides, silver metal oxides, titanium metal oxides, chromium metal oxides, tin metal oxides, cobalt metal oxides, tungsten metal oxides, molybdenum metal oxides, zinc metal oxides, and nickel metal oxides. Furthermore, the organic antioxidants of the weather-resistant layer 60 are conductive.

A method of making the composite current collector according to the preferred embodiment of the present invention comprises steps of:
S1) sputtering the connection layer 30 on the substrate 10;
S2) sputtering the insulation layer 40 on the connection layer 30;
S3) sputtering a seed layer 501 on the insulation layer 40;
S4) forming a metal layer 502 on the seed layer 501, wherein the conductive layer 50 is defined by the metal layer 502 and the seed layer 501;
S5) forming the weather-resistant layer 60 on the metal layer 502.
   In the step S4), the metal layer 502 is formed in an electroplating manner or an evaporating manner. In the step S5), the weather-resistant layer 60 is formed in any one of an electroplating manner, a chemical reacting manner, and a coating manner. The materials of the metal layer 502 are identical to the materials of the seed layer 501, wherein a thickness of the seed layer 5-1 is 2 nm to 100 nm, a thickness of the metal layer 502 is 0.5 nm to 5 nm. In other words, the conductive layer 50 includes the seed layer 501 and the metal layer 502, wherein the seed layer 501 is configured to enhance conductivity of the insulation layer 40 and to electroplate the metal layer 502 on the insulation layer 40 quickly.

Thereby, a battery is made of the composite current collector of the present invention to reduce the weight of the battery and to increase electrical energy of the battery.

The insulation layer 40 is defined between the connection layer 30 and the conductive layer 50 to stop the action of the connection layer 30 to the insulation layer 40, to maintain a connection of the connection layer 30 and the substrate 10, to avoid a removal of the connection layer 30 from the conductive layer 50, thus enhancing safety and service life of the composite current collector. The connection layer 30 and the insulation layer 40 are sputtered on the substrate 10, thus enhancing connection of the substrate 10, the connection layer 30, and the insulation layer 40.

In a comparative example 1, the substrate 10 is made of polyethylene terephthalate (PET) and a thickness of the substrate 10 is 4.5 microns. The conductive layer 50 is made of copper and a thickness of the conductive layer 50 is 1 micron, wherein the conductive layer 50 is formed on the substrate 10 directly.

In a comparative example 2, the substrate 10 is made of polyethylene terephthalate (PET) and a thickness of the substrate 10 is 4.5 microns. The connection layer 30 is made of chromium and a thickness of the connection layer 30 is 30 nm, wherein the conductive layer 50 is made of copper and a thickness of the conductive layer 50 is 1 micron.

In a first embodiment, the substrate 10 is made of PET and a thickness of the substrate 10 is 4.5 microns. The connection layer 30 is made of chromium and a thickness of the connection layer 30 is 20 nm, wherein the insulation layer 40 is made of Ni80Cr20 and a thickness of the insulation layer 40 is 15 nm, the conductive layer 50 is made of copper and a thickness of the conductive layer 50 is 1 micron. To compare the first embodiment with the comparative example 2, the insulation layer 40 is provided in the first embodiment. When forming the composite current collector in the first embodiment by using a sputtering machine, a transferring speed of the sputtering machine is 2 m/min, a sputtering power of the sputtering machine to the connection layer 30 is 4 KW, a sputtering power of the sputtering machine to the insulation layer 40 is 3 KW, a sputtering power of the sputtering machine to the seed layer 501 is 3 KW, and the seed layer 501 is sputtered six times by the sputtering machine, wherein the Ni80Cr20 is resistance alloys for electrical heating to obtain structural stability, stable electrical and physical properties, excellent high-temperature mechanics, cold deformation plasticity, weldability, and fracture toughness after a long period of using time.

The substrates 10 and the conductive layers 50 of the comparative example 1, the comparative example 1, and the first embodiment are identical, and the connection layers 30 of the comparative example 1 and the first embodiment are identical. According to a test method in IPC-TM-650 2.4.8, a peeling strength test of the comparative example 1, the comparative example 2 and the first embodiment are executed (it is noted that due to the thickness of the composite current collector of the present invention is thin, only the comparative example 1, the comparative example 2 and the first embodiment are tested, so the conductive layer 50 is thickened to a certain thickness before being tested). A peeling strength of the comparative example 1 is 0.2 kgf/cm-0.4 kgf/cm, a peeling strength of the comparative example 2 is 0.4 kgf/cm-0.7 kgf/cm, and a peeling strength of the first embodiment is 0.5 kgf/cm-0.8 kgf/cm. The comparative example 1, the comparative example 2 and the first embodiment 1 are simulated in a battery using environment, then the peeling strengths are tested again after 500 h time at 70° C. The peeling strength of the comparative example 1 is less than 0.2 kgf/cm, the peeling strength of the comparative example 2 is 0.2 kgf/cm-0.4 kgf/cm, and the peeling strength of the first embodiment is 0.4 kgf/cm-0.7 kgf/cm. It is seen that after the test, a connection section of the conductive layer 50 and the connection layer 30 produces a diffusion reaction so that connection strength of the connection layer 30 and the substrate 10 is reduced. After providing the insulation layer 40, reaction of the conductive layer 50 to the connection layer is eliminated to enhance connection strength of the composite portion 20 and the substrate 10, thus prolonging the service life of the composite current collector.

What is claimed is:

1. A composite current collector comprising:
a substrate (10);
a composite portion (20) formed on at least one surface of the substrate (10), wherein the composite portion (20) includes:
a connection layer (30) connected on the at least one surface of the substrate (10);
a conductive layer (50) located on the connection layer (30); and
an insulation layer (40) defined between the connection layer (30) and the conductive layer (50), wherein a first side of the insulation layer (40) is connected with the connection layer (30), and a second side of the insulation layer (40) is connected with the conductive layer (50), wherein the insulation layer (40) is configured to stop an action of the connection layer (30) to the conductive layer (50).

2. The composite current collector as claimed in claim 1, wherein the insulation layer is made of at least one of metals or alloys which include copper, aluminum, chromium, tin, cobalt, tungsten, zinc, and nickel.

3. The composite current collector as claimed in claim 1, wherein a thickness of the insulation layer is 2 nanometers (nm) to 50 nanometers (nm).

4. The composite current collector as claimed in claim 1, wherein the substrate is any one of polyethylene terephthalate (PET), polypropylene (PP), polyimide (PI), polycarbonate (PC), and poly (methyl methacrylate) (PMMA), wherein a thickness of the substrate is 2 microns to 15 microns.

5. The composite current collector as claimed in claim 1, wherein the connection layer is made of at least one of metals or alloys which include copper, aluminum, chromium, titanium, vanadium, niobium, cobalt, tungsten, molybdenum, zinc, and nickel, wherein a thickness of the connection layer is 2 nm to 50 nm.

6. The composite current collector as claimed in claim 2, wherein the conductive layer is made of at least one of copper, aluminum, lithium, gold, silver, titanium, molybdenum, zinc, and nickel.

7. The composite current collector as claimed in claim 6, wherein the insulation layer is made of different material from the material of the material of the conductive layer.

8. The composite current collector as claimed in claim 1, wherein the weather-resistant layer is made of any one of metals, alloys, metal oxides, and antioxidants, wherein the metals and the alloys of the weather-resistant layer include at least one of copper, aluminum, gold, silver, titanium, chromium, tin, cobalt, tungsten, molybdenum, zinc, and nickel, wherein thickness of the weather-resistant layer is 2 nm to 100 nm.

9. A method of making a composite current collector as claimed in claim 1, comprises steps of:
S1) sputtering the connection layer on the substrate;
S2) sputtering the insulation layer on the connection layer;
S3) sputtering a seed layer on the insulation layer;
S4) forming a metal layer on the seed layer, wherein the conductive layer is defined by the metal layer and the seed layer;
S5) forming the weather-resistant layer on the metal layer;
wherein in the step S4), the metal layer is formed in an electroplating manner or an evaporating manner;
wherein in the step S5), the weather-resistant layer is formed in any one of an electroplating manner, a chemical reacting manner, and a coating manner, the materials of the metal layer are identical to the materials of the seed layer, wherein a thickness of the seed layer 5-1 is 2 nm to 100 nm, a thickness of the metal layer is 0.5 nm to 5 nm.

10. A battery as claimed in claim 1 is made of the composite current collector.
